(19) United States
(12) Patent Application Publication
(10) Pub. No.: US 2012/0177078 A1
(43) Pub. Date: Jul. 12, 2012

(54) SURFACE-EMITTING LASER DIODE MODULE HAVING IMPROVED FOCUSING PERFORMANCE

(75) Inventor: HSIN-CHIH TUNG, TAO YUAN HSIEN (TW)

(73) Assignee: LECC TECHNOLOGY CO., LTD., TAOYUAN COUNTY (TW)

(21) Appl. No.: 13/177,505

(22) Filed: Jul. 6, 2011

(30) Foreign Application Priority Data
Jan. 12, 2011 (TW) 100200702

(51) Int. Cl. H01S 5/022

(52) U.S. Cl. 372/50.23

(57) ABSTRACT

A surface-emitting laser diode module having improved focusing performance includes a main body, a first support member, a second support member, a laser diode chip, and a focusing lens. The first and the second support members are disposed on the main body. One end of the first and the second support members is exposed in a trough formed on the main body. The other ends of the first and the second support members protrude from the main body and form a respective soldering portion. The laser diode chip is disposed on the first support member exposed in the trough and connected electrically to the second support member. The focusing lens is arranged at the light exit aligning the laser diode chip. The thinner and lighter laser diode module can provide better focus for dot or line laser applications.

### BACKGROUND OF THE INVENTION

1. Field of the Invention

The instant disclosure relates to a laser diode (LD) module; more particularly, to a surface-emitting laser diode module having improved focusing performance.

2. Description of Related Art

Generally, laser diodes include edge-emitting lasers (EEL) and surface-emitting lasers (VCSEL). Conventional surface-emitting lasers often require packaging by epoxy or other transparent materials. As a result, the light exit of the conventional diodes is covered by sealant that hinders the focusing performance thereof Thus, conventional surface-emitting lasers are limited to lighting applications but less ideal for dot or line application.

To address the above issue, the inventor proposes the following solution.

### SUMMARY OF THE INVENTION

The instant disclosure provides a surface-emitting laser diode module having improved focusing characteristic suitable for application in dot or line laser products.

According to one aspect of the instant disclosure, the surface-emitting laser diode module comprises: a main body having a trough formed thereon and a light exit is formed on one side thereof; a first and a second support members disposed on the main body, with one end of the first and the second support members exposed in the trough, and the other end of the first and the second support members each protruding from the main body to form a soldering portion; a laser diode chip fixed to the first support member exposed in the trough, wherein the laser diode chip is connected electrically to the second support member; and a focusing lens disposed at a distance apart from the light exit and aligned to the laser diode chip.

According to another aspect of the instant disclosure, a surface-emitting laser diode module comprises: a main body having a trough formed thereon, wherein a light exit is formed on one side of the main body; a first and second support members disposed on the main body, wherein one end of the first and second support members are exposed in the trough, wherein another end of the first and second support members each protrudes from the main body in forming a soldering portion; a laser diode chip fixed to the first support member exposed in the trough, wherein the laser diode chip is connected electrically to the second support member; and a focusing lens aligned to the laser diode chip.

According to further aspect of the instant disclosure, a surface-emitting laser diode module comprises: a main body having a trough formed thereon, wherein a light exit is formed on one side of the main body; a first and second conductors disposed on the main body, wherein the first and second conductors are exposed in the trough of the main body, wherein the first conductor is connected electrically to an external soldering portion, wherein the second conductor is connected electrically to another external soldering portion; a laser diode chip fixed to the first conductor exposed in the trough, wherein the laser diode chip is connected electrically to the second conductor; and a focusing lens aligned to the laser diode chip.

The instant disclosure has the following advantages. Firstly, the disclosed surface-emitting laser diode module does not need packaging material for packaging. At the light exit, a focusing lens is disposed without the sealant. Thereby, the module has excellent focusing effect suited for dot and line laser applications. In addition, the module is lighter and thinner.

Secondly, the disclosed laser diode module can be used as the light source of the optical touch screen. The module has faster response time versus the light-emitting diode, excellent sensitivity, and lower power consumption for energy saving.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1 shows a front view of a surface-emitting laser diode module without the focusing lens and the wave lens.

FIG. 2 shows a side view of the surface-emitting laser diode module without the focusing lens and the wave lens.

FIG. 3 shows a sectional view of the surface-emitting laser diode module.

FIG. 4 shows an exploded view of the surface-emitting laser diode module.

FIG. 5 shows a schematic view of the surface-emitting laser diode module in use.

FIG. 6 shows a front view of a surface-emitting laser diode module of another embodiment.

FIG. 7 shows a front view of a surface-emitting laser diode module of yet another embodiment.

FIG. 8 shows a front view of a surface-emitting laser diode module of still another embodiment.

### DETAILED DESCRIPTION OF PREFERRED EMBODIMENTS

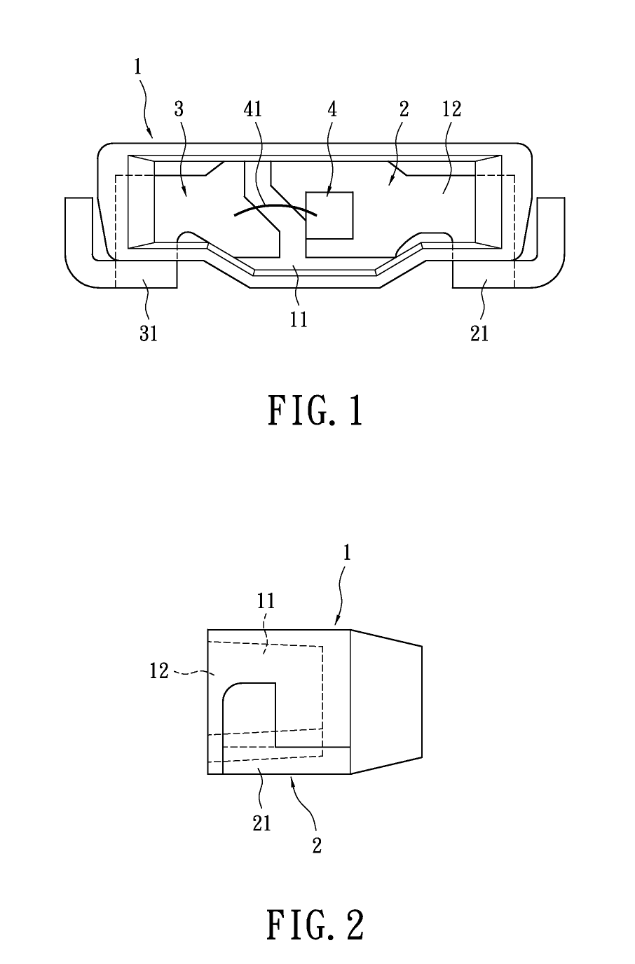

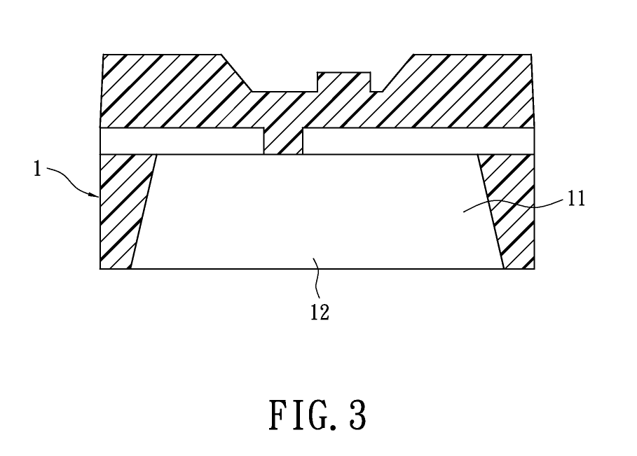

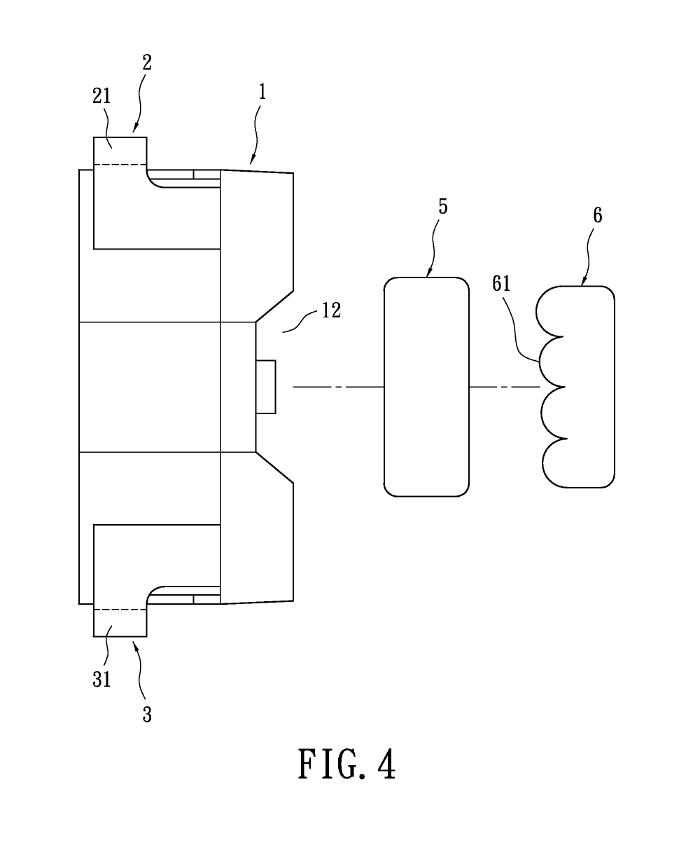

Please refer to FIGS. 1 thru 4, which show a surface-emitting laser diode module of a first embodiment, which comprises: a main body 1, a first support member 2, a second support member 3, a laser diode chip 4, and a focusing lens 5. The first and second support members 2 and 3 are manufactured by stamping the metal sheet (not shown) and disposed on the main body 1. More specifically, after the first and second support members 2 and 3 are made, insert molding is used to manufacture the main body 1, wherein a trough 11 is formed thereon. Thereby, one end of the first and second support members 2 and 3 are exposed in the trough 11. The exposed ends are separated by a pre-determined distance. For the instant embodiment, the main body 1 is made of plastic material, but is not limited thereto. Ceramic and other materials may also be used. The other end of the first and second support members 2 and 3 each extends off the respective side of the main body 1 in forming soldering portions 21 and 31 respectively. The soldering portions 21 and 31 can be bent into an L-shape or any other shape. As part of a surface mount device (SMD), the soldering potions 21 and 31 can be directly mounted onto the circuit board by soldering. Hence, the surface-emitting laser diode module can be connected electrically to the circuit board.

Based on the surface mount technology (SMT), the laser diode chip 4 is mounted onto the first support member 2 exposed in the trough 11 of the main body 1. Next, wire bonding or flip chip bonding method is used to connect the laser diode chip 4 electrically to the second support member 3. For the instant embodiment, the wire bonding technique is used, wherein a conductive wire 41 connects the laser diode chip 4 to the second support member 3.

A light exiting port 12 is formed on one side of the main body 1. The light exiting port 12 is aligned with the trough 11. The focusing lens 5 is disposed at a distance apart from the light exiting port 12. The focusing lens 5 can be secured to a desired location (e.g. housing) of the device and is aligned with the laser diode chip 4. Thereby, the laser beam off the laser diode chip 4 can converge and focus accordingly.

A wave lens 6 (or a cylindrical lens) can be disposed on one side of the focusing lens 5. In other words, the focusing lens 5 is in between the wave lens 6 and the laser diode chip 4. The wave lens 6 has a wavy surface 61 on one side, wherein the wavy surface 61 is not restricted structurally, which can be varied on an application basis. Once the laser beam off the laser diode chip 4 is converged by the focusing lens 5, the laser beam is refracted through the wave lens 6 and projected as a line or a cross.

The disclosed surface-emitting laser diode module does not need packaging material for packaging. At the light exiting port 12, a focusing lens 5 is disposed without the sealant. Thereby, the module has excellent focusing effect suited for dot and line laser applications. In addition, the module is lighter and thinner.

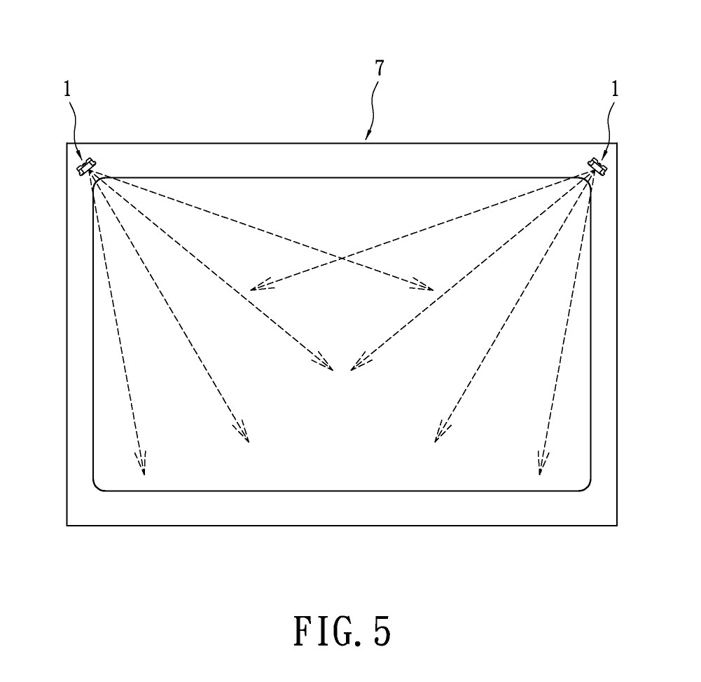

Please refer to FIG. 5, which shows the surface-emitting laser diode module being used as the light source for the optical touch screen 7. Placed on the side, one or two laser diode module can be included per touch screen. Lower power consumption is achieved, versus conventional optical touch screen that requires a plurality of light-emitting diodes. Thereby, the laser diode module provides energy saving, along with excellent sensitivity and fast response time.

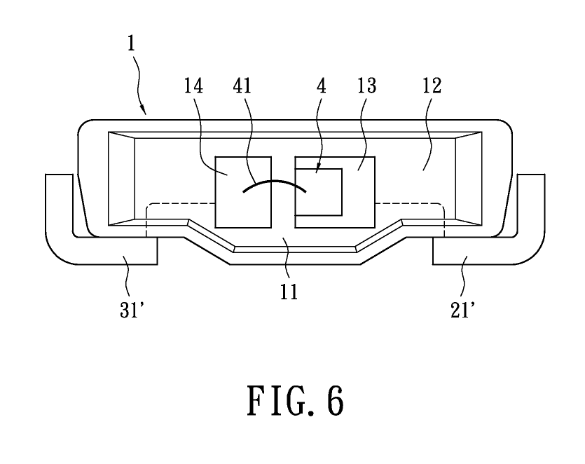

Please refer to FIG. 6, which shows a surface-emitting laser diode module for another embodiment of the instant disclosure. The surface-emitting laser diode module comprises the main body 1, the laser diode chip 4, and the focusing lens (not shown). For the instant embodiment, the first and second support members are omitted in favor of disposing a first conductor 13 and a second conductor 14 on the main body 1. The first and second conductors 13 and 14 are exposed in the trough 11 of the main body 1. The first conductor 13 is wired to an external soldering portion 21′ for electrical connection. Likewise, the second conductor 14 is wired to another soldering portion 31′. The soldering portions 21′ and 31′ are both L-shaped as surface mount devices (SMD), which can be mounted directly onto the circuit board by soldering. The laser diode chip 4 is fixed to the first conductor 13, which is exposed in the trough 11 of the main body 1. The laser diode chip 4 is connected electrically to the second conductor 14 by wire bonding or flip chip bonding method. For the instant embodiment, the wire bonding technique is used, wherein the conductive wire 41 connects the laser diode chip 4 to the second conductor 14. The focusing lens (not shown) is aligned with the laser diode chip 4. Also, a wave lens or a cylindrical lens (not shown) can be disposed on one side of the focusing lens.

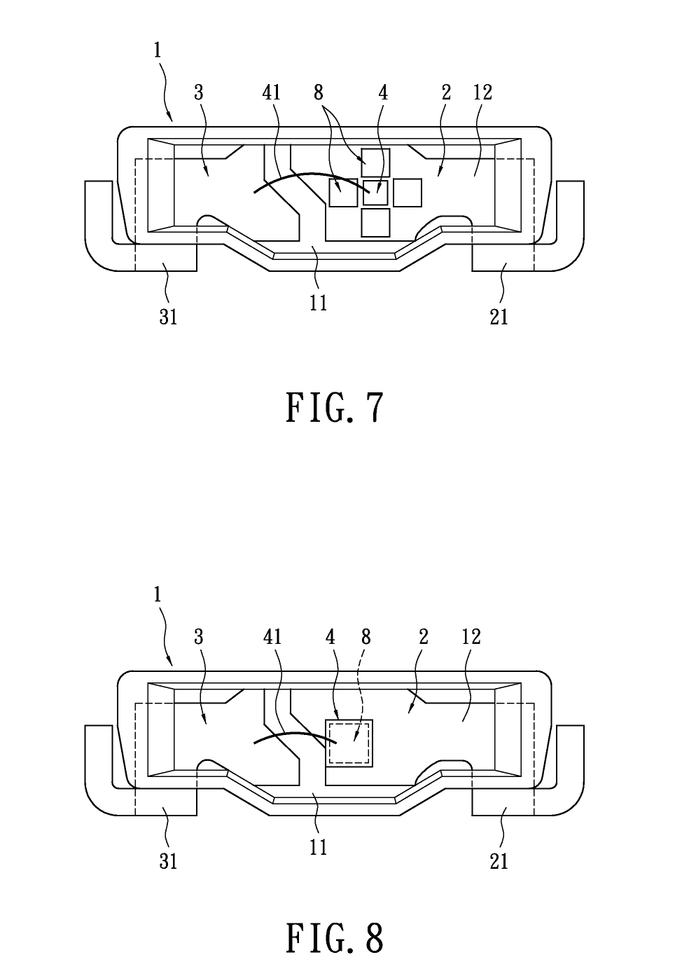

Please refer to FIG. 7, which shows yet another embodiment of the instant disclosure. Namely, the laser diode chip 4 is surrounded by two to four photo detectors (PD) 8 to monitor the light emission therefrom. Thus, a constant light emission rate can be maintained.

Please refer to FIG. 8, which further shows another embodiment of the instant disclosure. Namely, the photo detector (PD) 8 is arranged under the laser diode chip 4. In other words, the laser diode chip 4 is disposed directly over the photo detector (PD) 8.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A surface-emitting laser diode module, comprising:
a main body having a trough formed thereon and a light exiting port formed on one side thereof;
a first support member and a second support member disposed on the main body, wherein one end of each first and the second support members is respectively exposed in the trough of the main body, wherein the other end of each first and the second support members respectively protrudes from the main body to form a soldering portion;
a laser diode chip fixed to the first support member exposed in the trough of the main body, wherein the laser diode chip is connected electrically to the second support member; and
a focusing lens arranged at the light exiting port of the main body and aligns the laser diode chip.

2. The surface-emitting laser diode module of claim 1, wherein the respective soldering portions of the first and second members are surface-mounted elements.

3. The surface-emitting laser diode module of claim 2, wherein the soldering portions of the first and second support members are L-shaped.

4. The surface-emitting laser diode module of claim 1, wherein a wave lens or a cylindrical lens is disposed on one side of the focusing lens.

5. The surface-emitting laser diode module of claim 1, wherein the laser diode chip is connected electrically to the second support member by wire bonding or flip chip bonding.

6. The surface-emitting laser diode module of claim 1, wherein at least one photo detector is disposed adjacently or below the laser diode chip.

7. A surface-emitting laser diode module, comprising:
a main body having a trough formed thereon and a light exiting port formed on one side thereof;
a first support member and a second support member disposed on the main body, wherein one end of each first and the second support members is exposed in the trough of the main body, wherein the other end of each first and the second support members respectively protrudes from the main body to form a soldering portion;
a laser diode chip disposed on the first support member exposed in the trough of the main body and connected electrically to the second support member; and
a focusing lens alignedly arranged with respect to the laser diode chip.

8. The surface-emitting laser diode module of claim 7, wherein the respective soldering portions of the first and second members are surface-mounted elements.

9. The surface-emitting laser diode module of claim 8, wherein the soldering portions of the first and second support members are L-shaped.

10. The surface-emitting laser diode module of claim 7, wherein a wave lens or a cylindrical lens is disposed on one side of the focusing lens.

11. The surface-emitting laser diode module of claim 7, wherein the laser diode chip is connected electrically to the second support member by wire bonding or flip chip bonding.

12. The surface-emitting laser diode module of claim 7, wherein at least one photo detector is disposed adjacently or below the laser diode chip.

13. A surface-emitting laser diode module, comprising:
a main body having a trough formed thereon and a light exiting port formed on one side thereof;
a first conductor and a second conductor disposed on the main body, wherein the first and the second conductors are exposed in the trough of the main body, wherein the first conductor is connected electrically to a first soldering portion external of the main body, wherein the second conductor is connected electrically to a second soldering portion external of the main body;
a laser diode chip disposed on the first conductor exposed in the trough of the main body and connected electrically to the second conductor; and
a focusing lens alignedly arranged with respect to the laser diode chip.

14. The surface-emitting laser diode module of claim 13, wherein the soldering portion are surface-mounted elements.

15. The surface-emitting laser diode module of claim 14, wherein the soldering portions are L-shaped.

16. The surface-emitting laser diode module of claim 13, wherein a wave lens or a cylindrical lens is disposed on one side of the focusing lens.

17. The surface-emitting laser diode module of claim 13, wherein the laser diode chip is connected electrically to the second conductor by wire bonding or flip chip bonding.

18. The surface-emitting laser diode module of claim 13, wherein at least one photo detector is disposed adjacently or below the laser diode chip.
